(19) United States
(12) Patent Application Publication
(10) Pub. No.: US 2017/0365459 A1
(43) Pub. Date: Dec. 21, 2017

(54) METHOD FOR MANUFACTURING SEMICONDUCTOR DEVICE AND RECORDING MEDIUM

(71) Applicant: HITACHI KOKUSAI ELECTRIC INC., Tokyo (JP)

(72) Inventor: Naofumi OHASHI, Toyama-shi (JP)

(73) Assignee: HITACHI KOKUSAI ELECTRIC INC., Tokyo (JP)

(21) Appl. No.: 15/696,923

(22) Filed: Sep. 6, 2017

Related U.S. Application Data
(63) Continuation of application No. PCT/JP2015/058521, filed on Mar. 20, 2015.

(51) Int. Cl. H01L 21/02

(52) U.S. Cl. CPC H01L 21/0234; H01L 21/02326; H01L 21/02164; H01L 21/02222; H01L 21/02282

(57) ABSTRACT

To reduce a hydroxy group in a silicon oxide film formed at a low temperature and obtain a silicon oxide film with an excellent film quality, (a) accommodating a substrate on a surface of which a silicon oxide film formed at a processing temperature of 300° C. or lower is formed in a processing container, (b) plasma-exciting a hydrogen gas, and a step of supplying hydrogen active species generated in (b) to the substrate are performed.

### TECHNICAL FIELD

The present teachings relate to a method of manufacturing a semiconductor device for processing a substrate by using plasma and a recording medium.

### BACKGROUND ART

With miniaturization of a large scale integrated circuit (hereinafter, LSI), technical difficulties in processing technology of controlling leakage current interference between transistor devices are increasing. In order to perform device isolation of the LSI, for example, a method of forming voids such as grooves or holes between the devices desired to be separated on silicon (Si) serving as a substrate, and depositing an insulator in the void is adopted. An oxide film is often used as the insulator and, for example, a silicon oxide film is used. The silicon oxide film is formed by various methods such as oxidation of the Si substrate itself, a chemical vapor deposition method (CVD method), an insulator applying method (SOD method) and the like.

In a film forming step of forming the oxide film, in order to reduce damage that the device such as the transistor already formed on the substrate receives by heat, a demand for performing the film forming step under a low temperature condition is also increasing. For example, Patent Literature 1 discloses forming a silicon oxide film by oxidizing a silicon-containing film formed by being applied to a substrate by the SOD method at a low temperature with a hydrogen peroxide gas.

### CITATION LIST

### Patent Literature

### Patent Literature 1: WO2014/157210

### SUMMARY OF TEACHINGS

### Technical Problem

However, when the film forming step is performed under a low temperature condition, there is a problem that a film quality may be lowered as compared with the case where the film formation is performed under a high temperature condition as in the conventional case. Particularly in the case of forming the silicon oxide film, dehydrocondensation reaction of a hydroxy group progresses in the film forming step under a high temperature condition as in the conventional art, so that the hydroxy group remaining in the film is rarely a problem in practical use. However, when the silicon oxide film is formed under a low temperature condition, the dehydrocondensation reaction of the hydroxy group in the film formation step is inhibited, so that the hydroxy group in the film might remain beyond an allowable range of the film quality. If the hydroxy group remains in the film beyond an allowable amount, a hygroscopic property of the silicon oxide film increases, so that adsorbed moisture problematically decreases a withstand voltage performance as an insulator or a chemical resistance performance.

The present teachings provide technology that makes it possible to obtain a film with an excellent characteristic with little hydroxy group residual even with the oxide film formed at a low temperature.

### Solution to Problem

According to one aspect of the present teachings, there is provided technology for performing steps of accommodating a substrate on a surface of which a silicon oxide film formed at a processing temperature of 300° C. or lower, is formed in a processing container, plasma-exciting a hydrogen gas, and supplying hydrogen active species generated at the step of plasma-exciting the hydrogen gas to the substrate.

According to the technology according to the present teachings, even with a silicon oxide film formed at a low temperature, it is possible to obtain a film with excellent characteristics with few in-film defects.

### BRIEF DESCRIPTION OF DRAWINGS

FIG. 1 is a schematic configuration diagram of a substrate processing apparatus preferably used at a film forming processing step according to a first embodiment.

FIG. 2 is a schematic longitudinal cross-sectional view of a processing furnace included in the substrate processing apparatus preferably used at the film forming processing step according to the first embodiment.

FIG. 3 is a schematic configuration diagram of a controller of the substrate processing apparatus preferably used at the film forming processing step according to the first embodiment.

FIG. 4 is a hydrogen peroxide vapor generating device included in the substrate processing apparatus preferably used in the first embodiment.

FIG. 5 is a flowchart illustrating an example of the film forming processing step according to the first embodiment.

FIG. 6 is a schematic configuration diagram of the substrate processing apparatus preferably used at a modifying processing step according to the first embodiment.

FIG. 7 is a schematic configuration diagram of a controller of the substrate processing apparatus preferably used at the modifying processing step according to the first embodiment.

FIG. 8 is a flowchart illustrating an example of the modifying processing step according to the first embodiment.

FIG. 9 is a graph comparing characteristics of the silicon oxide film subjected to the modifying process according to the first embodiment and a silicon oxide film according to a comparative example.

FIG. 10 is a schematic configuration diagram of another substrate processing apparatus used at the modifying processing step according to the first embodiment.

FIG. 11 is a schematic configuration diagram of still another substrate processing apparatus used at the modifying processing step according to the first embodiment.

### DESCRIPTION OF EMBODIMENTS

### First Embodiment

A first embodiment is hereinafter described. In this embodiment, a film forming processing step A for forming a silicon oxide film on a substrate and a modifying processing step B for modifying the silicon oxide film formed on the substrate at the film forming processing step A using plasma are performed by a film forming processing apparatus 100 and a modifying processing apparatus 50, respectively. The silicon oxide film in this embodiment refers to a film having stoichiometric composition such as a SiO₂ film, for example, and a film having composition different from the stoichiometric composition represented by SiOx. Hereinafter, they are also simply referred to as SiO films.

(1-1) Configuration of Film Forming Processing Apparatus 100 (Apparatus Regarding Film Forming Processing Step A)

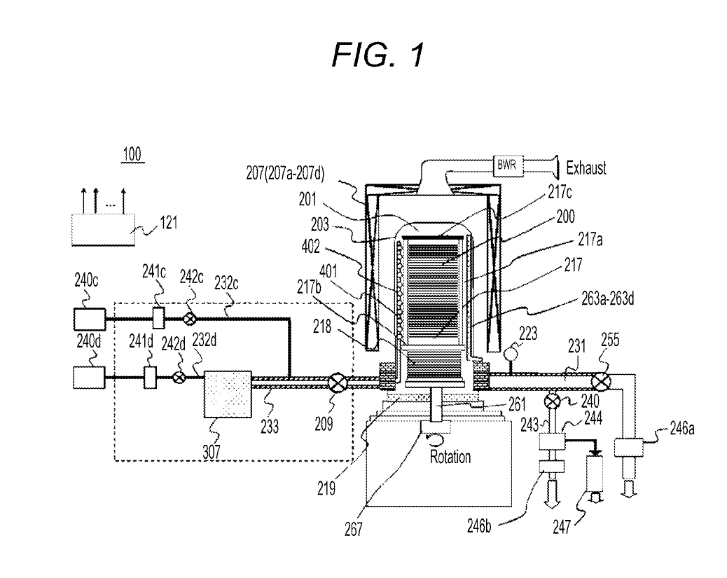

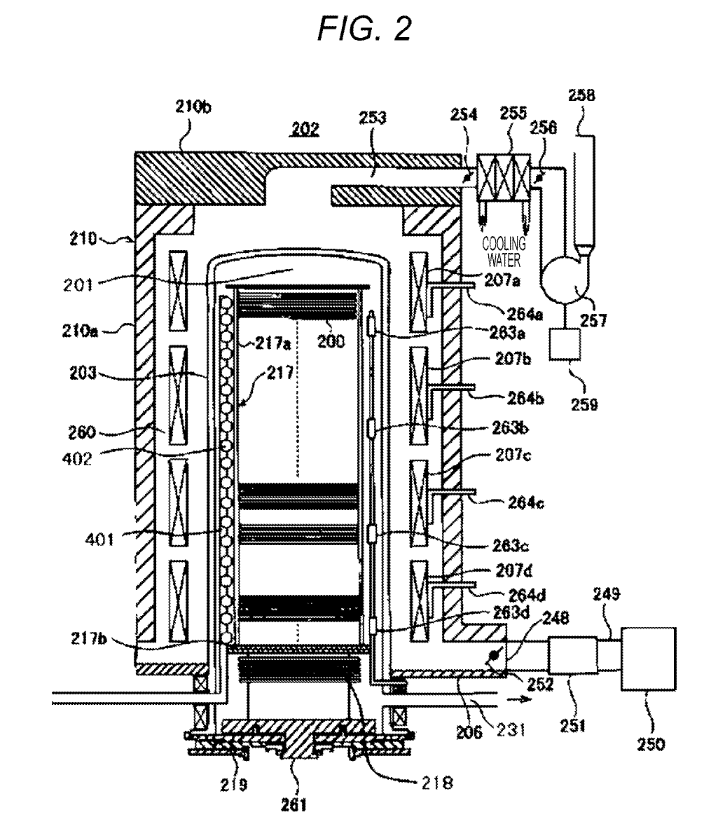

First, a configuration of the film forming processing apparatus 100 according to this embodiment is described primarily with reference to FIGS. 1 and 2. FIG. 1 is a schematic configuration diagram of the film forming processing apparatus 100 regarding a film forming step of this embodiment. FIG. 2 is a schematic longitudinal cross-sectional view of a processing furnace 202 provided on the film forming processing apparatus 100.

(Reaction Tube)

As illustrated in FIG. 1, the processing furnace 202 is provided with a reaction tube 203. The reaction tube 203 made of, for example, a heat resistant material obtained by combining quartz (SiO₂) and silicon carbide (SiC), or a heat resistant material such as quartz or SiC, is formed into a cylindrical shape with upper and lower ends opened. A processing chamber 201 is formed in a cylindrical hollow portion of the reaction tube 203 in order to be able to accommodate wafers 200 as substrates in a horizontal posture in a state arranged in multiple stages in a vertical direction by a boat 217 described later.

A seal cap 219 as a furnace opening lid body capable of air-tightly sealing (blocking) the lower end opening (furnace opening) of the reaction tube 203 is provided in a lower portion of the reaction tube 203. The seal cap 219 is configured to abut the lower end of the reaction tube 203 from a lower side in the vertical direction. The seal cap 219 is formed into a disc shape. The processing chamber 201 serving as a processing space of the substrate is formed of the reaction tube 203 and the seal cap 219.

(Substrate Supporting Unit)

The boat 217 as a substrate retainer is configured to be able to hold a plurality of wafers 200 in multiple stages. The boat 217 is provided with a plurality of support columns 217a for holding a plurality of wafers 200. A plurality of support columns 217a is installed between a bottom plate 217b and a top plate 217c. A plurality of wafers 200 is aligned by the support columns 217a in the horizontal posture in a state in which their centers are aligned to be held in multiple stages in a tube axis direction.

A heat insulator 218 made of a heat resistant material such as quartz or SiC, for example, is provided on a lower portion of the boat 217 so that heat from a heating unit 207 is hardly transmitted to a side of the seal cap 219. The heat insulator 218 serves as a heat insulating member and also serves as a holding body for holding the boat 217. The heat insulator 218 may also be considered as one of components of the boat 217.

(Lifting Unit)

A boat elevator as a lifting unit which lifts up and down the boat 217 to transfer to the inside and outside of the reaction tube 203 is provided below the reaction tube 203. The boat elevator is provided with the seal cap 219 for sealing the furnace opening when the boat 217 is lifted up by the boat elevator.

A boat rotating mechanism 267 for rotating the boat 217 is provided on a side opposite to the processing chamber 201 of the seal cap 219. A rotating shaft 261 of the boat rotating mechanism 267 penetrating the seal cap 219 to be connected to the boat 217 is configured to rotate the wafer 200 by rotating the boat 217.

(Heating Unit)

The heating unit 207 for heating the wafer 200 in the reaction tube 203 is provided concentrically around a side wall surface of the reaction tube 203 on an outer side of the reaction tube 203. The heating unit 207 is provided while being supported by a heater base 206. As illustrated in FIG. 2, the heating unit 207 is provided with first to fourth heater units 207a to 207d. Each of the first to fourth heater units 207a to 207d is provided in a stacking direction of the wafers 200 in the reaction tube 203.

In the reaction tube 203, first to fourth temperature sensors 263a to 263d such as thermocouples, for example, are provided between the reaction tube 203 and the boat 217 as temperature detectors for detecting temperature of the wafer 200 or ambient temperature for the first to fourth heater units 207a to 207d, respectively. The first to fourth temperature sensors 263a to 263d may also be provided in order to detect the temperature of the wafer 200 located at the center of a plurality of wafers 200 heated by the first to fourth heater units 207a to 207d, respectively.

A controller 121, which will be described in detail hereinafter, is electrically connected to each of the heating unit 207 and the first to fourth temperature sensors 263a to 263d. The controller 121 is configured to control electric power supplied to each of the first to fourth heater units 207a to 207d at predetermined timing on the basis of temperature information detected by each of the first to fourth temperature sensors 263a to 263d such that the temperature of the wafer 200 in the reaction tube 203 reaches predetermined temperature and to individually perform temperature setting and temperature regulation for each of the first to fourth heater units 207a to 207d.

(Gas Supply Unit (Gas Supply System))

As illustrated in FIG. 1, a gas supply pipe 233 as a gas supply unit for supplying a vaporized gas as a processing gas into the reaction tube 203 is provided outside the reaction tube 203. The gas supply pipe 233 is connected to a gas supply nozzle 401 provided in the reaction tube 203. The gas supply nozzle 401 is provided in the stacking direction of the wafers 200 from the lower portion to the upper portion of the reaction tube 203. The gas supply nozzle 401 is provided with a plurality of gas supply holes 402 so that the vaporized gas may be uniformly supplied into the reaction tube 203.

A raw material, the boiling point of which is 50 to 200° C., is used as a raw material of the vaporized gas. In this embodiment, an example of using the vaporized gas of liquid containing hydrogen peroxide (H₂O₂), especially hydrogen peroxide water as a solution containing hydrogen peroxide as a raw material, is described. Note that, when deterioration in processing efficiency or quality is particularly allowed, water vapor (H₂O) without containing hydrogen peroxide may also be used.

As illustrated in FIG. 1, a hydrogen peroxide vapor generating device 307 is connected to the gas supply pipe 233. A hydrogen peroxide water source 240d, a liquid flow rate controller 241d, and a valve 242d are connected to the hydrogen peroxide vapor generating device 307 in this order from an upstream side through a hydrogen peroxide water supply pipe 232d. Hydrogen peroxide water, a flow rate of which is adjusted by the liquid flow rate controller 241d, may be supplied to the hydrogen peroxide vapor generating device 307.

An inert gas supply pipe 232c, a valve 242c, a mass flow controller (MFC) 241c, and an inert gas supply source 240c are provided on the gas supply pipe 233 so that an inert gas may be supplied.

The gas supply unit is formed of the gas supply nozzle 401, the gas supply holes 402, the gas supply pipe 233, the hydrogen peroxide vapor generating device 307, the hydrogen peroxide water supply pipe 232d, the valve 242d, the liquid flow rate controller 241d, the inert gas supply pipe 232c, the valve 242c, the MFC 241c, and a valve 209. The hydrogen peroxide water source 240d and the inert gas supply source 240c may also be included in the gas supply unit.

In the first embodiment, since the hydrogen peroxide water is used, it is preferable that a portion with which hydrogen peroxide is brought into contact in the film forming processing apparatus 100 is formed of a material hardly reacting with the hydrogen peroxide. As the material hardly reacting with hydrogen peroxide, there may be ceramics such as Al₂O₃, AlN, and SiC and quartz.

(Hydrogen Peroxide Vapor Generating Device)

The hydrogen peroxide vapor generating device 307 illustrated in FIG. 4 uses a dripping method of dripping raw material liquid on a heated member to vaporize the raw material liquid. The hydrogen peroxide vapor generating device 307 is formed of a drip nozzle 300 as a liquid supply unit for supplying the hydrogen peroxide water, a vaporizing container 302 as the member to be heated, a vaporization space 301 formed of the vaporizing container 302, a vaporizer heater 303 as a heating unit for heating the vaporizing container 302, an exhaust port 304 for exhausting the vaporized raw material liquid to a reaction chamber, a thermocouple 305 for measuring temperature of the vaporizing container 302, a temperature control controller 400 for controlling temperature of the vaporizer heater 303 on the basis of the temperature measured by the thermocouple 305, and a chemical supply pipe 232d for supplying the raw material liquid to the drip nozzle 300. The vaporizing container 302 is heated by the vaporizer heater 303 so that the dripped raw material liquid is vaporized at the same time as this reaches the vaporizing container. A heat insulating material 306 capable of improving heating efficiency of the vaporizing container 302 by the vaporizer heater 303 and insulating heat between the hydrogen peroxide vapor generating device 307 and other units is provided. The vaporizing container 302 is made of quartz, SiC and the like in order to prevent reaction with the raw material liquid. The temperature of the vaporizing container 302 decreases due to the temperature of the dripped raw material liquid and vaporization heat. Therefore, it is effective to use SiC with high thermal conductivity in order to prevent the temperature from decreasing.

(Exhaust Unit (Exhaust System))

One end of a gas exhaust pipe 231 for exhausting the gas in the substrate processing chamber 201 is connected to the lower portion of the reaction tube 203. The other end of the gas exhaust pipe 231 is connected to a vacuum pump 246a (exhaust device) through an auto pressure controller (APC) valve 255. The substrate processing chamber 201 is exhausted by negative pressure generated by the vacuum pump 246a. The APC valve 255 is an opening/closing valve capable of exhausting and stopping exhausting the substrate processing chamber 201 by opening and closing the valve. This is also a pressure regulating valve capable of regulating pressure by adjusting a degree of valve opening.

A pressure sensor 223 as a pressure detector is provided on an upstream side of the APC valve 255. In this manner, it is configured to vacuum-exhaust so that the pressure in the substrate processing chamber 201 reaches predetermined pressure (degree of vacuum). A pressure control unit 284 is electrically connected to the substrate processing chamber 201 and the pressure sensor 223 by the APC valve 255; the pressure control unit 284 is configured to control at desired timing such that the pressure in the substrate processing chamber 201 reaches desired pressure by the APC valve 255 on the basis of the pressure detected by the pressure sensor 223.

The exhaust unit is formed of the gas exhaust pipe 231, the APC valve 255, the pressure sensor 223 and the like. The vacuum pump 246a may also be included in the exhaust unit.

(Control Unit)

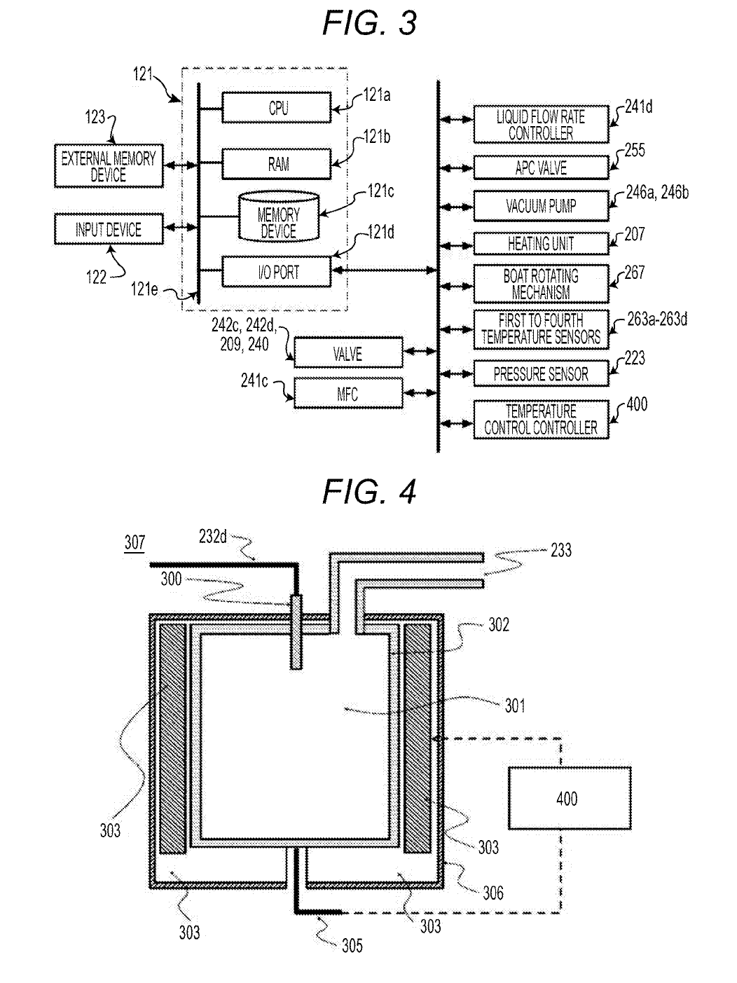

As illustrated in FIG. 3, the controller 121 which is a control unit (control means) is configured as a computer provided with a central processing unit (CPU) 121a, a random access memory (RAM) 121b, a memory device 121c, and an I/O port 121d. The RAM 121b, the memory device 121c, and the I/O port 121d are configured to be able to exchange data with the CPU 121a through an internal bus 121e. An input/output device 122 configured as, for example, a touch panel and the like is connected to the controller 121.

The memory device 121c is formed of, for example, a flash memory, a hard disk drive (HDD) and the like. In the memory device 121c, a control program for controlling operation of the substrate processing apparatus, a program recipe in which procedures and conditions of a substrate process described later are written and the like are readably stored. A process recipe being a combination of procedures at the film forming processing step A, described in greater detail hereinafter, so that the controller 121 may execute the same to obtain a predetermined result serves as a program. Hereinafter, the program recipe, the control program and the like are simply collectively referred to as a program. In the present specification, the term of “program” might include only the program recipe alone, only the control program alone, or both of them. The RAM 121b is configured as a memory area (work area) in which programs, data and the like read out by the CPU 121a are temporarily held.

The I/O port 121d is connected to the above-described liquid flow rate controller 241d, MFC 241c, valves 242c, 242d, 209, and 240, APC valve 255, heating unit 207 (207a, 207b, 207c, and 207d), first to fourth temperature sensors 263a to 263d, boat rotating mechanism 267, pressure sensor 223, temperature control controller 400 and the like.

The CPU 121a is configured to read out to execute the control program from the memory device 121c and read out the process recipe from the memory device 121c in accordance with an input of an operation command from the input/output device 122 and the like. The CPU 121a is configured to control flow rate adjusting operation of the liquid material by the liquid flow rate controller 241d, flow rate adjusting operation of the inert gas by the MFC 241c, opening/closing operation of the valves 242c, 242d, 209, and 240, opening/closing adjusting operation of the APC valve 255, temperature regulating operation of the heating unit 207 based on the first to fourth temperature sensors 263a to 263d, start/stop of the vacuum pumps 246a and 246b, rotation speed adjusting operation of the boat rotating mechanism 267, and the hydrogen peroxide vapor generating device 307 and the like by the temperature control controller 400.

(1-2) Film Forming Processing Step A

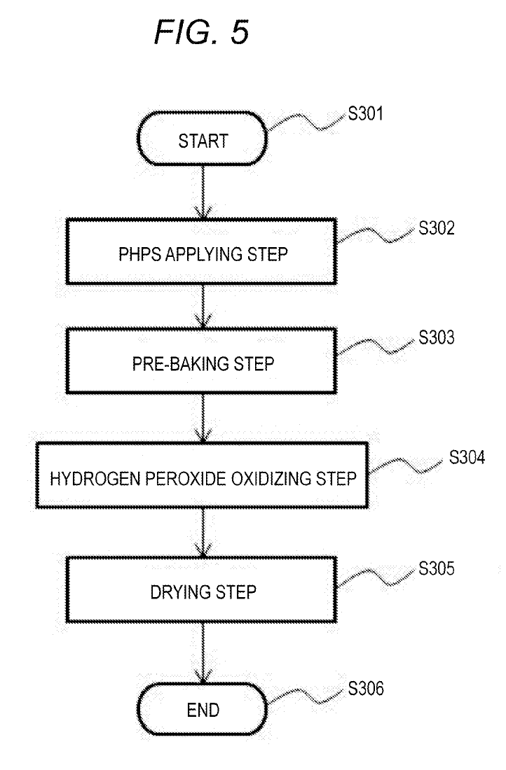

FIG. 5 illustrates the film forming processing step A according to the first embodiment. The film forming processing step A according to the first embodiment includes applying step S302 of applying an oxide film material formed by an applying method, pre-baking step S303 of drying a solvent component in the film after application, oxidizing step S304 of exposing to or immersing in the hydrogen peroxide water after drying, and drying step S305 of washing with pure water after exposure to or immersion in the hydrogen peroxide water to dry.

(Applying Step S302)

At applying step S302, the oxide film material is applied onto the wafer 200 carried in the processing chamber, for example, by a spin coating method. Herein, the oxide film material is polysilazane (perhydro-polysilazane (PHPS)). Minute unevenness is formed on the wafer 200. The minute unevenness is formed of, for example, a trench between a gate insulating film and a gate electrode, or minute semiconductor devices.

(Pre-Baking Step S303)

At pre-baking step S303, pre-baking to heat the wafer 200 to which PHPS is applied, evaporate the solvent in the applied PHPS, and to cure the PHPS is performed. The wafer 200 is heated by the heating unit 207 provided in the processing chamber. Specifically, when the wafer 200 is heated to approximately 70° C. to 250° C., the solvent in the PHPS volatilizes. This is more desirably heated at 150° C. or lower. It is also possible to simultaneously heat a plurality of wafers 200 in a state in which a plurality of wafers 200 is accommodated.

(Hydrogen Peroxide Oxidizing Step S304)

At hydrogen peroxide oxidizing step S304, hydrogen peroxide is supplied to the wafer 200 on which a PHPS film is formed. By supply of hydrogen peroxide, the PHPS film is oxidized and the silicon oxide film is formed. Hydrogen peroxide is supplied to the wafer 200 while rotating the wafer 200.

Hydrogen peroxide oxidizing step S304 is described in more detail. When the wafer 200 is heated and the wafer 200 reaches desired temperature and the boat 217 reaches a desired rotation speed, the hydrogen peroxide water is started to be supplied from the liquid material supply pipe 232d to the hydrogen peroxide vapor generating device 307. That is, the valve 242d is opened, and the hydrogen peroxide water is supplied from the hydrogen peroxide water source 240d to the hydrogen peroxide vapor generating device 307 through the liquid flow rate controller 241d.

The hydrogen peroxide water supplied to the hydrogen peroxide vapor generating device 307 is dripped from the drip nozzle 300 to a bottom of the vaporizing container 302. The vaporizing container 302 is heated to desired temperature by the vaporizer heater 303, and droplets of dripped hydrogen peroxide water is heated by an inner wall of the vaporizing container 302 and evaporated to be gas. Since decomposition of hydrogen peroxide is promoted as the temperature rises, it is desirable that temperature of the vaporizer heater 303 remain low when generating the vaporized gas of hydrogen peroxide. However, when the temperature of the vaporizer heater 303 is too low, it is not possible to stably vaporize the hydrogen peroxide water droplets, so that the temperature of the vaporizer heater 303 is desirably set to, for example, 200° C. or lower, preferably approximately from 150 to 170° C.

Vaporized hydrogen peroxide water (vapor of hydrogen peroxide water) is supplied as the vaporized gas to the wafer 200 accommodated in the substrate processing chamber 201 through the gas supply pipe 233, the gas supply nozzle 401, and the gas supply holes 402.

Hydrogen peroxide contained in the vaporized gas of hydrogen peroxide water is subjected to oxidation reaction with the PHPS film (silicon-containing film) formed on the surface of the wafer 200, thereby modifying the PHPS film to the silicon oxide film.

Since hydrogen peroxide (H₂O₂) has a simple structure in which hydrogen is bonded to an oxygen molecule, this has a characteristic that this easily penetrates into a low-density medium. Hydrogen peroxide decomposes to generate a hydroxy radical (OH*). The hydroxy radical is a type of active oxygen and is a neutral radical in which oxygen and hydrogen are bonded to each other. The hydroxy radical has strong oxidizing power. The PHPS film on the wafer 200 is oxidized by the hydroxy radical generated by decomposition of the supplied hydrogen peroxide, and the silicon oxide film is formed. That is, a silazane bond (Si—N bond) and a Si—H bond which the PHPS film has are cleaved by the oxidizing power of the hydroxy radical. Then, cleaved nitrogen (N) and hydrogen (H) are replaced with oxygen (O) which the hydroxy radical has to form a Si—O bond in the silicon-containing film. As a result, the PHPS film is oxidized to be modified to the silicon oxide film.

The vaporized gas of hydrogen peroxide water is supplied into the reaction tube 203, and is exhausted by using the vacuum pump 246b and a liquid recovery tank 247. That is, when the APC valve 255 is closed and the valve 240 is opened, the exhaust gas exhausted from the reaction tube 203 passes through a separator 244 from the gas exhaust pipe 231 through a second exhaust pipe 243. After separating the exhaust gas into liquid containing hydrogen peroxide and gas containing no hydrogen peroxide by the separator 244, the gas is exhausted from the vacuum pump 246b and the liquid is recovered in the liquid recovery tank 247.

When the hydrogen peroxide water is supplied into the reaction tube 203, it is also possible to close the valve 240 and the APC valve 255 to pressurize the interior of the reaction tube 203. According to this, a hydrogen peroxide water atmosphere in the reaction tube 203 may be made uniform.

After a predetermined time elapses, the valves 242d and 209 are closed to stop supplying the vaporized gas of hydrogen peroxide water into the reaction tube 203.

Although it is described that the hydrogen peroxide water is supplied to the hydrogen peroxide vapor generating device 307 to supply the vaporized gas of hydrogen peroxide water into the substrate processing chamber 201, there is no limitation, and liquid containing ozone (O₃) and the like may also be used, for example. Additionally, when deterioration in processing efficiency or quality is particularly allowed, a vaporized gas of water (H₂O) (vapor) may also be used.

Not only the vaporized gas of hydrogen peroxide water but also a gas containing hydrogen such as a hydrogen gas (H₂ gas), for example, and a vaporized (H₂O) gas obtained by heating the gas containing oxygen such as an oxygen gas (O₂ gas), for example, may be used as the processing gas. As an oxygen-containing gas, in addition to an O₂ gas, for example, an ozone gas (O₃ gas), water vapor (H₂O) and the like may also be used.

As another embodiment, a chemical tank may be provided in the processing chamber, the hydrogen peroxide water may be stored in the chemical tank in advance, and the wafer 200 may be immersed in the hydrogen peroxide water.

(Drying Step S305)

At drying step S305, pure water is supplied to the wafer 200 to remove hydrogen peroxide and a by-product, and the wafer 200 is dried. It is preferable to supply pure water while rotating the wafer 200. Pure water is supplied by a pure water supply nozzle (not illustrated). Drying is performed by rotation of the wafer 200. When the wafer 200 is rotated, centrifugal force acts on moisture on the wafer 200 to remove the same. Alternatively, it is also possible to dry the wafer 200 by supplying an alcohol, replacing the moisture with the alcohol, and then removing the alcohol. The alcohol is supplied to the wafer 200 in a vaporized state. Alternatively, an alcohol solution may be dripped onto the wafer. Alternatively, it is also possible to provide a heating element (not illustrated) in the processing chamber to heat the wafer 200 to appropriate temperature, thereby promoting removal of the alcohol. As the heating element, for example, a lamp heater (not illustrated), a resistance heating heater (not illustrated) and the like is used. As the alcohol, for example, an isopropyl alcohol (IPA) is used. Drying step S305 may also be performed in a state in which a plurality of wafers 200 is accommodated in the processing chamber.

The steps from applying step S302 to drying step S305 may be performed in the same processing chamber, or each step may be performed by providing separate processing chambers such as an applying processing chamber in which the applying step is performed, a pre-baking processing chamber in which the pre-baking step is performed, an oxidizing/drying processing chamber in which the oxidizing step and the drying step are performed.

Even in a case of processing the wafer 200 in the separate processing chambers, it is also possible to perform a batch process in which two or more substrates are processed at the same time at each step. It is possible to improve processing throughput of the substrate by simultaneously processing two or more substrates.

A series of steps from applying step S302 to drying step S305 is performed so that the temperature of the wafer 200 is always 300° C. or lower, preferably 200° C. or lower, and more preferably 150° C. or lower. It is possible to reduce thermal damage received by a device and a pattern formed on the wafer 200 by keeping the temperature of the wafer 200 at a certain temperature or lower in this manner. According to the film forming processing step A, it is possible to form the silicon oxide film on the wafer 200 especially while keeping the temperature of the wafer 200 at 150° C. or lower. Furthermore, also in a modifying process using hydrogen plasma described later, by keeping the temperature of the wafer 200 at a certain temperature or lower (that is, 300° C. or lower, preferably 200° C. or lower, more preferably 150° C. or lower), it is possible to similarly reduce the thermal damage to the wafer 200. Also, in a series of steps, the temperature of the wafer 200 is set to 0° C. or higher (preferably, room temperature (25° C.) or higher), and more desirably 70° C. at which the solvent in the PHPS film is volatilized or higher at pre-baking step S303, for example, and the temperature at which the vaporized gas of the hydrogen peroxide water does not liquefy (for example, 100° C.) at hydrogen peroxide oxidizing step S304.

However, when the silicon oxide film is formed under a low temperature condition as at the film forming processing step A in this embodiment, dehydration condensation reaction of a hydroxy group (hydroxyl group) in the film forming process is inhibited, so that the hydroxy groups are contained in the film at a high rate. The hydroxy group contained in the silicon oxide film exists as an in-film defect (deficit). A hygroscopic property of the silicon oxide film having such defect increases, and withstand voltage decreases due to the adsorbed moisture, so that there might be a problem that performance as the insulating film deteriorates. Similarly, there might be a problem that the silicon oxide film having such defect has low chemical resistance performance, in particular, low resistance to an etching solution such as hydrofluoric acid (high wet etching rate (WER)). Especially, the silicon oxide film formed at a process temperature of 300° C. or lower as in this embodiment has the high ratio of the hydroxy groups contained in the film as compared with other film forming methods in which film formation is performed at the process temperature of 400° C. or higher, and there might be a problem that this is inferior in withstand voltage performance and chemical resistance performance.

For this reason, it is considered that the silicon oxide film formed under the low temperature condition (especially 300° C. or lower) is modified by heating treatment (annealing) to repair the in-film defect. For example, in a nitrogen atmosphere, the silicon oxide film is heated at 400° C. or higher for a predetermined time. However, since performing the heating treatment causes the thermal damage to the device and pattern formed on the wafer as described above, it is desirable not to perform such heating treatment.

Therefore, in this embodiment, at the modifying processing step B described below, the silicon oxide film formed under the low temperature condition is subjected to the modifying process using hydrogen plasma. As a result, the defect due to the hydroxy group in the film is repaired to improve a film quality of the silicon oxide film formed under the low temperature condition.

(2-1) Configuration of Modifying Processing Apparatus 50 (Apparatus Performing Modifying Processing Step)

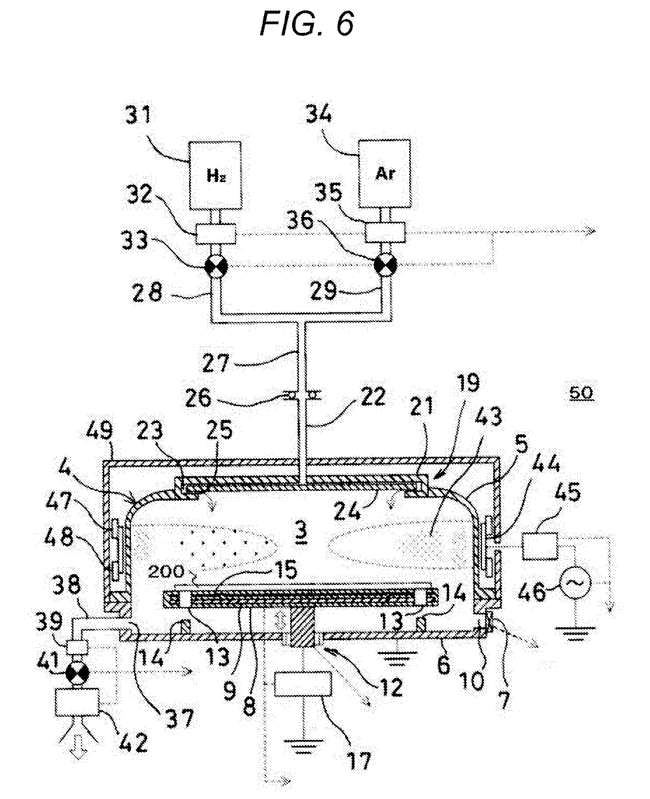

A configuration of the substrate processing apparatus 50 (hereinafter referred to as modifying processing apparatus 50) regarding the modifying processing step of the first embodiment is described primarily with reference to FIG. 6.

FIG. 6 illustrates the modifying processing apparatus 50 configured as an MMT apparatus. The modifying processing apparatus 50 is an apparatus which uses a modified magnetron-type plasma source capable of generating high-density plasma by an electric field and a magnetic field to perform a plasma process on the wafer 200 subjected to the film forming process by the film forming processing apparatus 100. The modifying processing apparatus 50 may excite the processing gas to perform the modifying process on the silicon oxide film formed on the wafer 200.

(Processing Chamber)

A processing container 4 forming the processing chamber 3 includes a dome-shaped upper container 5 as a first container and a bowl-shaped lower container 6 as a second container. By putting the upper container 5 on the lower container 6, the processing chamber 3 is formed. The upper container 5 is made of a nonmetallic material such as aluminum oxide (Al₂O₃) and quartz, for example, and the lower container 6 is made of, for example, aluminum (Al) and the like.

On a side wall of the lower container 6, a gate valve 7 as a gate valve is provided. When the gate valve 7 is opened, the wafer 200 may be carried in the processing chamber 3 or the wafer 200 may be carried out of the processing chamber 3 through a carry-in/carry-out port 10 by a transferring mechanism (not illustrated). It is possible to air-tightly block the interior of the processing chamber 3 by closing the gate valve 7.

A susceptor 8 as a substrate supporting unit which supports the wafer 200 is arranged at the center of a bottom side in the processing chamber 3. The wafer 200 is placed on a substrate placement surface 8a of the susceptor 8. The susceptor 8 is made of a non-metallic material such as aluminum nitride (AlN), ceramics, quartz and the like, for example, so that metal contamination of the wafer 200 may be reduced. The susceptor 8 is electrically insulated from the lower container 6.

(Susceptor)

A heater 9 as a heating mechanism arranged in parallel with the substrate placement surface 8a is integrally embedded inside the susceptor 8 so that the wafer 200 may be heated. By supplying electric power to the heater 9, it is possible to heat the surface of the wafer 200 to predetermined temperature (for example, room temperature to approximately 300° C.). A temperature sensor (not illustrated) is provided on the susceptor 8, and a controller 500 described later is electrically connected to the heater 9 and the temperature sensor. The controller 500 is configured to control the electric power supplied to the heater 9 on the basis of temperature information detected by the temperature sensor.

The susceptor 8 is provided with a susceptor lifting mechanism 12 for lifting up and down the susceptor 8. A through-hole 13 is formed on the susceptor 8 and at least three wafer push-up pins 14 for pushing up the wafer 200 are provided on a bottom surface of the lower container 6. The through-hole 13 and the wafer push-up pin 14 are arranged so that when the susceptor 8 is lifted down by the susceptor lifting mechanism 12, the wafer push-up pin 14 penetrates the through-hole 13 in a non-contacting state with the susceptor 8.

As illustrated in FIG. 6, an impedance variable electrode 15 for controlling the potential of the wafer 200 is provided inside the susceptor 8. The impedance variable electrode 15 is arranged in parallel with the substrate placement surface 8a and may uniformly adjust the potential of the wafer 200. An impedance adjusting unit 17 capable of changing an impedance value is connected to the impedance variable electrode 15 as a substrate potential distribution adjusting unit. The impedance adjusting unit 17 is provided with a coil 171 and a variable capacitor 172 connected in series. It is configured such that the impedance of the impedance adjusting unit 17 may be changed by adjustment of electrostatic capacitance of the variable capacitor 172. It is configured such that, when the impedance of the impedance adjusting unit 17 is changed, the potential of the impedance variable electrode 15 with respect to the plasma, that is, the potential of the wafer 200 immediately above the impedance variable electrode 15 is controlled. The impedance adjusting unit 17 is connected to the controller 500.

Herein, there is a proportional relationship between the electrostatic capacitance adjusted by the impedance adjusting unit 17 and an amount of the plasma attracted. Specifically, the larger the electrostatic capacitance is, the more the plasma is attracted, and the smaller the electrostatic capacitance is, the smaller the amount of the plasma attracted. Therefore, it is possible to control a processing speed of the film and a depth of a gas component to be penetrated into the film by adjusting a drawing amount of active species and the like in the plasma into the wafer 200 by adjusting the variable capacitor 172.

(Gas Supply Unit (Gas Supply System))

As illustrated in FIG. 6, a shower head 19 for supplying the processing gas into the processing chamber 3 is provided in an upper portion of the processing chamber 3. The shower head 19 is provided with a cap-shaped lid body 21, a gas introducing unit 22, a buffer chamber 23, a shielding plate 24, and a gas ejection port 25.

The lid body 21 is air-tightly provided on an opening formed in an upper portion of the upper container 5. The shielding plate 24 is provided on a lower portion of the lid body 21, and a space formed between the lid body 21 and the shielding plate 24 serves as the buffer chamber 23. The buffer chamber 23 serves as a dispersing space for dispersing the processing gas introduced from the gas introducing unit 22. The processing gas which passes through the buffer chamber 23 is supplied into the processing chamber 3 from the gas ejection port 25 on a side portion of the shielding plate 24. An opening is provided on the lid body 21, and a downstream end of the gas introducing unit 22 is air-tightly connected to the opening of the lid body 21. A downstream end of the gas supply pipe 27 is connected to an upstream end of the gas introducing unit 22 through an O ring 26 as a sealing member. It is also possible to supply the processing gas to the processing chamber 3 in a dispersed manner by providing a shower plate including a large number of gas passage holes in place of the shielding plate 24.

On an upstream side of the gas supply pipe 27, a downstream end of a processing gas supply pipe 28 which supplies hydrogen (H₂) gas as the processing gas and a downstream end of an inert gas supply pipe 29 which supplies an argon (Ar) gas or a helium (He) gas, for example, as the inert gas are connected to be joined together. In this embodiment, the Ar gas is used as the inert gas. The gas supply pipe 27, the processing gas supply pipe 28, and the inert gas supply pipe 29 are made of a nonmetallic material such as quartz and aluminum oxide, a metal material such as SUS and the like, for example.

A processing gas supply source 31, an MFC 32 as a flow rate control device, and a valve 33 as an on/off valve are connected to the processing gas supply pipe 28 in this order from an upstream side. An inert gas supply source 34, an MFC 35 as a flow rate control device, and a valve 36 as an on/off valve are connected to the inert gas supply pipe 29 in this order from an upstream side. The Ar gas being the inert gas is used as a diluent gas of the processing gas, a carrier gas of the processing gas, or a purge gas for replacing a gas atmosphere.

A controller 11 is electrically connected to the MFC 32 and the valve 33. The controller 11 is configured to control an opening degree of the MFC 32 and opening/closing of the valve 33 so that the flow rate of the processing gas supplied into the processing chamber 3 becomes a predetermined flow rate. By opening/closing the valve 33 and further controlling the flow rate by the MFC 32, it is possible to freely supply the H₂ gas as the processing gas into the processing chamber 3 through the gas supply pipe 27, the buffer chamber 23, and the gas ejection port 25.

The controller 11 is electrically connected to the MFC 35 and the valve 36. The controller 11 is configured to control an opening degree of the MFC 35 and opening/closing of the valve 36 so that the flow rate of the inert gas mixed with the processing gas or the inert gas supplied to the processing chamber 3 becomes a predetermined flow rate. The gas of a predetermined flow rate is mixed with the processing gas by control of the valve 36 and the MFC 35. Also, by controlling the valve 36 and the MFC 35, it is possible to freely supply the Ar gas which is the inert gas into the processing chamber 3 through the gas supply pipe 27, the buffer chamber 23, and the gas ejection port 25.

The gas supply unit (gas supply system) in a first example is mainly formed of the shower head 19, the gas supply pipe 27, the processing gas supply pipe 28, the inert gas supply pipe 29, the MFCs 32 and 35, and the valves 33 and 36. The processing gas supply source 31 and the inert gas supply source 34 may also be included in the gas supply unit.

(Exhaust Unit (Exhaust System))

A gas exhaust port 37 for exhausting the processing gas and the like from the processing chamber 3 is provided on a lower portion of a side wall of the lower container 6. An upstream end of a gas exhaust pipe 38 for exhausting the gas is connected to the gas exhaust port 37. An APC valve 39 being a pressure regulator, a valve 41 which is an on/off valve, and a vacuum pump 42 which is an exhaust device are provided on the gas exhaust pipe 38 in this order from an upstream thereof. An exhaust unit (exhaust system) according to this embodiment is mainly formed of the gas exhaust port 37, the gas exhaust pipe 38, the APC valve 39, and the valve 41. The vacuum pump 42 may also be included in the exhaust unit.

The controller 11 is electrically connected to the APC valve 39, the valve 41, and the vacuum pump 42, and it is possible to exhaust the processing chamber 3 by operating the vacuum pump 42 and opening the valve 41. It is possible to regulate the pressure in the processing chamber 3 by adjusting an opening degree of the APC valve 39.

(Plasma Generating Unit)

On an outer periphery of the processing container 4 (upper container 5), a tubular electrode 44 is provided in order to surround a plasma generating region 43 in the processing chamber 3. The tubular electrode 44 is formed into a tubular shape, for example, a cylindrical shape, and is connected to a high-frequency power source 46 which generates high-frequency power through a matching device 45 which performs impedance matching. The tubular electrode 44 serves as a discharging mechanism for exciting the processing gas supplied into the processing chamber 3.

An upper magnet 47 and a lower magnet 48 are attached to upper and lower ends of an outer surface of the tubular electrode 44, respectively. Each of the upper magnet 47 and the lower magnet 48 is formed as a permanent magnet formed into a tubular shape, for example, a ring shape. The upper magnet 47 and the lower magnet 48 have magnetic poles on both ends in a radial direction of the processing chamber 3, that is, on an inner peripheral end and an outer peripheral end of each magnet. The upper magnet 47 and the lower magnet 48 are arranged such that directions of magnetic poles thereof are opposite to each other. That is, the magnetic poles of inner peripheral portions of the upper magnet 47 and the lower magnet 48 are opposite poles, so that a magnetic force line in a cylindrical axis direction is formed along an inner surface of the tubular electrode 44.

After supplying at least the O₂ gas into the processing chamber 3, high-frequency power is applied to the tubular electrode 44 to form an electric field and a magnetic field is formed by using the upper magnet 47 and the lower magnet 48, so that magnetron discharge plasma is generated in the plasma generating region 43 in the processing chamber 3. At that time, by allowing emitted electrons to circulate around the above-described electric field and magnetic field, an ionization generation rate of the plasma is increased and high-density plasma with long life may be generated.

The plasma generating unit in this embodiment is mainly formed of the tubular electrode 44, the matching device 45, the high-frequency power source 46, the upper magnet 47, and the lower magnet 48.

A shielding plate 49 made of metal which effectively shields the electric field and the magnetic field is provided around the tubular electrode 44, the upper magnet 47, and the lower magnet 48 so that the electric field and the magnetic field formed by them do not adversely affect an external environment and devices such as other processing furnace.

(Control Unit)

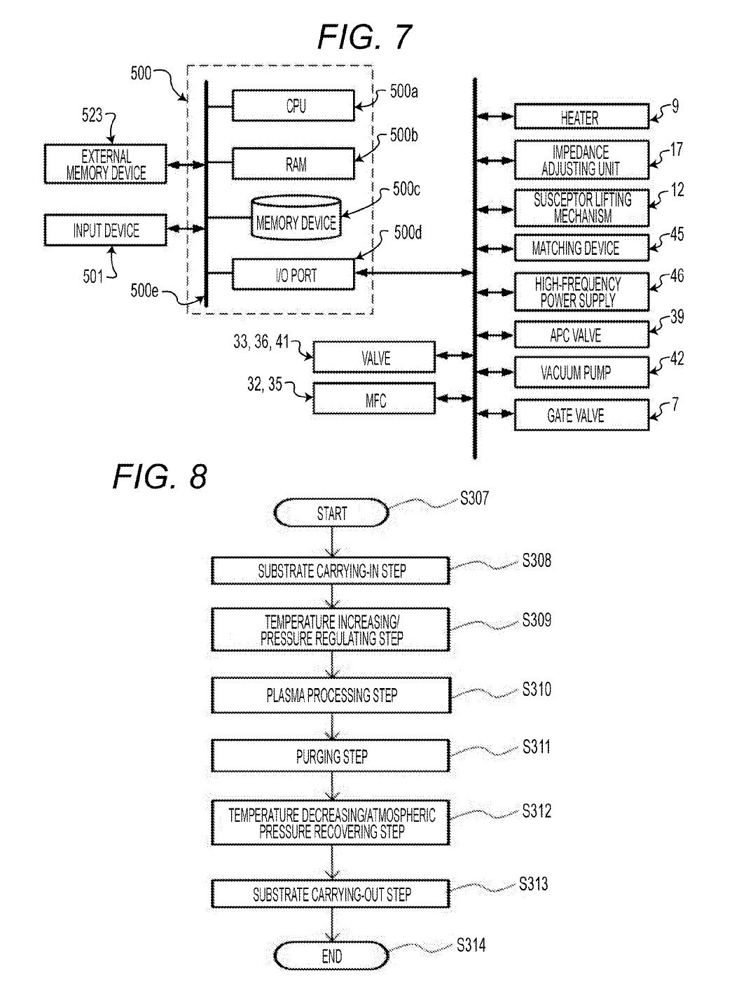

As illustrated in FIG. 7, the controller 500 which is a control unit (control means) is configured as a computer provided with a central processing unit (CPU) 521a, a random access memory (RAM) 521b, a memory device 521c, and an I/O port 521d. The RAM 521b, the memory device 521c, and the I/O port 521d are configured to be able to exchange data with the CPU 521a through the internal bus 521e. An input/output device 522 configured as a touch panel and the like is connected, for example, to the controller 500.

The memory device 521c is formed of, for example, a flash memory, a hard disk drive (HDD) and the like. In the memory device 521c, a control program for controlling operation of the substrate processing apparatus, a program recipe in which procedures and conditions of substrate processing described later are written and the like are readably stored. A process recipe being a combination of procedures at the modifying processing step B described later so that the controller 500 may execute the same to obtain a predetermined result serves as a program. Hereinafter, the program recipe, the control program and the like are simply collectively referred to as a program. In the present specification, the term of “program” might include only the program recipe alone, only the control program alone, or both of them. The RAM 521b is configured as a memory area (work area) in which programs, data and the like read out by the CPU 521a are temporarily held.

The I/O port 521d is connected to the above-described valves 33, 36, and 41, MFCs 32 and 35, heater 9, impedance adjusting unit 17, susceptor lifting mechanism 12, matching device 45, high-frequency power source 46, APC valve 39, vacuum pump 42, gate valve 7 and the like.

The CPU 521a is configured to read out to execute the control program from the memory device 521c and read out the process recipe from the memory device 521c in accordance with the input of the operation command from the input/output device 522 and the like. The CPU 521a is configured to control opening/closing operation of the valves 33, 36, and 41, the flow rate adjusting operation of the H₂ gas and the Ar gas by the MFCs 32 and 35, the opening/closing adjusting operation of the APC valve 39, temperature regulating operation of the heater 9 based on the temperature sensor, start/stop of the vacuum pump 42, potential adjustment of the impedance variable electrode 15 by the impedance adjusting unit 17, operation of the matching device 45 and the high-frequency power source 46, operation of the susceptor lifting mechanism 12 and the like along contents of the read out process recipe.

The controllers 121 and 500 provided on the film forming processing apparatus 100 and the modifying processing apparatus 50 according to this embodiment may be configured by installing the above-described program stored in external memory devices (for example, magnetic tapes, magnetic disks such as flexible disks and hard disks, optical disks such as CDs and DVDs, photomagnetic disks such as an MO, as semiconductor memories such as a USB memory and a memory card) 123 and 523 in a computer. The memory devices 121c and 521c and the external memory devices 123 and 523 are configured as computer readable recording media. Hereinafter, they are collectively and simply referred to as recording media. In the present specification, the term “recording medium” might include only a single unit of each of the memory devices 121c and 521c, only a single unit of each of the external memory devices 123 and 523, or both. The program may be provided to the computer by using communication means such as the Internet and a dedicated line without using the external memory devices 123 and 523.

Also, the controller 500 may be connected to a communication network through the I/O port 521d and connected to the controller 121 of the film forming processing apparatus 100. The controller 121 and the controller 500 may be connected to a higher-order controller (not illustrated) of the film forming processing apparatus 100 and the modifying processing apparatus 50 through a communication network, thereby forming one film forming/modifying processing system.

(2-2) Modifying Processing Step B

Subsequently, the substrate modifying processing step B according to the first embodiment is described with reference to a flowchart of FIG. 8. At the modifying processing step B according to the first embodiment, the silicon oxide film formed on the surface of the wafer 200 at the film forming processing step A according to the first embodiment is subjected to the modifying process with hydrogen plasma by using the above-described modifying processing apparatus 50. In the following description, the operation of each unit forming the modifying processing apparatus 50 is controlled by the controller 500.

(Substrate Carrying-in Step S308)

The wafer 200 on the surface of which the silicon oxide film is formed at the film forming processing step A according to the first embodiment is carried in the processing chamber 3. That is, first, the susceptor 8 is lifted down to a transferring position of the wafer 200 and the wafer push-up pins 14 are allowed to penetrate the through-holes 13 of the susceptor 8, so that the wafer push-up pins 14 are projected by a predetermined height from the surface of the susceptor 8. Subsequently, the gate valve 7 is opened and the wafer 200 is carried in the processing chamber 3 by using a transferring mechanism not illustrated. As a result, the wafer 200 is supported in the horizontal posture on the wafer push-up pins 14 protruding from the surface of the susceptor 8.

When the wafer 200 is carried in the processing chamber 3, the transferring mechanism is withdrawn to the outside of the processing chamber 3, and the gate valve 7 is closed to tightly seal the inside of the processing chamber 3. Next, by lifting up the susceptor 8 by using the susceptor lifting mechanism 12, the wafer 200 is placed on the upper surface of the susceptor 8. Thereafter, the susceptor 8 is lifted up to a predetermined position, and the wafer 200 is lifted up to a predetermined processing position.

When the wafer 200 is carried in the processing chamber 3, it is preferable to supply the N₂ gas as the purge gas from the gas supply unit to the processing chamber 3 while exhausting the processing chamber 3 by the exhaust unit. That is, it is preferable to supply the N2 gas into the processing chamber 3 through the buffer chamber 23 by operating the vacuum pump 42, opening the valve 41 to exhaust the processing chamber 3, and opening the valve 36. As a result, entry of particles into the processing chamber 3 and adhesion of the particles on the wafer 200 may be inhibited. The vacuum pump 42 is always kept in operation at least from substrate carrying-in step S308 until substrate carrying-out step S313 described later is finished.

(Temperature Increasing/Pressure Regulating Step S309)

Subsequently, electric power is supplied to the heater 9 embedded in the susceptor 8 to heat such that temperature of the surface of the wafer 200 reaches predetermined temperature. At that time, the temperature of the heater 9 is regulated by control of the electric power supplied to the heater 9 on the basis of temperature information detected by a temperature sensor (not illustrated). Herein, in this embodiment, in order to inhibit the device and pattern formed on the wafer 200 from being damaged by heat, the wafer 200 is heated to predetermined temperature within a range not lower than 0° C. (preferably, room temperature (25° C.) or higher) and not higher than 300° C. (preferably 200° C. or lower, more preferably 150° C. or lower). By heating in order to realize film forming processing temperature at which the silicon oxide film is formed at the film forming processing step A (that is, 300° C. or lower, preferably 200° C. or lower, and more preferably 150° C. or lower), it is possible to apply this modifying processing step B to the wafer 200 without giving the wafer 200 damage more than thermal damage at the film forming processing step A. As the temperature of the wafer 200 at the modifying processing step B is higher, a modifying effect described later is higher, so that the temperature of the wafer 200 is preferably set to 0° C. or higher, more preferably room temperature (25° C.) or higher.

When performing this modifying process at the room temperature, it is not necessary to heat the wafer 200. When the surface of the wafer 200 exceeds predetermined temperature at plasma processing step S310 described later, a chiller not illustrated for cooling the wafer 200 may be provided inside the susceptor 8 in addition to the heater 9. That is, the controller 500 controls the chiller, or both the chiller and the heater 9 in order to regulate the temperature so that the surface of the wafer 200 does not exceed the predetermined temperature or maintains the predetermined temperature.

The processing chamber 3 is vacuum-exhausted by the vacuum pump 42 so that the pressure in the processing chamber 3 reaches desired pressure. At that time, the pressure in the processing chamber 3 is measured by a pressure sensor not illustrated, and the controller 500 feedback-controls the opening degree of the APC valve 39 on the basis of the pressure measured by the pressure sensor. In order to perform plasma processing step S310 described later, it is desirable that the pressure in the processing chamber 3 is set to a pressure within a range of 1 Pa to 500 Pa capable of generating plasma, and 50 Pa to 200 Pa more suitable for plasma generation.

(Plasma Processing Step S310)

Hereinafter, an example in which the plasma processing step is performed by using the H₂ gas as the processing gas is described.

First, the valve 33 is opened, and the H₂ gas as the processing gas is supplied from the processing gas supply pipe 28 to the processing chamber 3 through the buffer chamber 23. At that time, the opening degree of the mass flow controller 32 is adjusted so that the flow rate of the H₂ gas becomes a predetermined flow rate.

When supplying the H₂ gas as the processing gas into the processing chamber 3, it is preferable to supply the Ar gas as the carrier gas or the dilution gas from the inert gas supply pipe 29 into the processing chamber 3. That is, it is preferable to supply the Ar gas into the processing chamber 3 through the buffer chamber 23 by opening the valve 36 and adjusting the flow rate by the mass flow controller 35. As a result, the supply of the H₂ gas into the processing chamber 3 may be promoted.

After the supply of the processing gas is started, predetermined high-frequency power (for example, 100 W to 1000 W, preferably 100 W to 500 W) is applied to the tubular electrode 44 where the magnetic field is formed by the upper magnet 47 and the lower magnet 48 from the high-frequency power source 46 through the matching device 45 for a predetermined time (for example, 180 seconds). As a result, magnetron discharge occurs in the processing chamber 3, and high-density plasma is generated in the plasma generating region 43 above the wafer 200. In this manner, by generating the plasma, the H₂ gas supplied into the processing chamber 3 is excited to be activated, the active species such as hydrogen radicals contained in the excited H₂ gas are supplied onto the wafer 200, and the silicon oxide film formed on the wafer 200 is modified.

At that time, the hydrogen radical (H*) exerts a strong reducing action on the silicon oxide film and reacts with the hydroxy group (hydroxyl group) which is the defect in the silicon oxide film, thereby showing a remarkable defect repairing effect. It is considered that the reaction represented below, for example, occurs with the hydroxy group in the SiO₂ film.

Si−OH+H*→Si*+H−OH

Si−OH+Si*+H*→Si−O−Si+H−H

That is, the hydroxy group bonded to a silicon atom (Si) in the film is cleaved from the silicon atom by the supplied hydrogen radical and is bonded to a hydrogen atom. Furthermore, the hydroxy group bonded to the hydrogen atom is decomposed by reaction with a silicon radical (Si*) and the hydrogen radical, and an oxygen atom is bonded to the silicon atom, thereby repairing the defect of the SiO₂ film present by the hydroxy group. In this manner, at the plasma processing step according to this embodiment, the defect of the SiO₂ film present by the hydroxy group is repaired by the reaction with the hydrogen radical and film density is improved, so that the film quality of the SiO₂ film (silicon oxide film) (withstand voltage performance, chemical resistance performance and the like) is improved.

At the plasma processing step in this embodiment, by changing the impedance on the basis of the electrostatic capacitance of the variable capacitor 172 connected to the impedance variable electrode 15, the potential of a processing surface of the wafer 200 is changed, thereby controlling the amount of active species in the plasma to be drawn into the wafer 200.

(Purging Step S311)

After the lapse of a predetermined time, the electric power supply to the tubular electrode 44 is stopped to finish the plasma processing step. Thereafter, the valve 33 is closed, which stops supplying the H₂ gas into the processing chamber 3. At that time, the valve 41 is kept open to continuously exhaust by the gas exhaust pipe 38, and a residual gas and the like in the processing chamber 3 are exhausted. By opening the valve 36 and supplying the N₂ gas as the purge gas into the processing chamber 3, exhaust of the residual gas from the processing chamber 3 may be promoted.

(Temperature Decreasing/Atmospheric Pressure Recovering Step S312)

After the purging step is completed at purging step S311, the temperature of the wafer 200 is decreased to predetermined temperature (for example, room temperature to 100° C.) while recovering the pressure in the processing chamber 3 to atmospheric pressure by adjusting the opening degree of the APC valve 39. Specifically, the opening degree of the APC valve 39 and that of the valve 41 of the exhaust unit are controlled on the basis of pressure information detected by a pressure sensor not illustrated while supplying the N₂ gas into the processing chamber 3 while keeping the valve 36 open to raise the pressure in the processing chamber 3 to the atmospheric pressure, and the amount of power supplied to the heater 9 is controlled to decrease the temperature of the wafer 200.

(Substrate Carrying-Out Step S313)

The susceptor 8 is then lifted down to the transferring position of the wafer 200, and the wafer 200 is supported on the wafer push-up pins 14 projected from the surface of the susceptor 8. Finally, the gate valve 7 is opened, the wafer 200 is carried out of the processing chamber 3 by using the transferring mechanism not illustrated, and the modifying processing step B in this embodiment is finished.

### Effect of this Embodiment

### Comparison with Comparative Example

An effect of the modifying process of the silicon oxide film by using the hydrogen plasma in this embodiment is described in comparison with a following comparative example. A case where the film forming process was carried out under a temperature condition illustrated in following Table 1 as the comparative example was estimated. A case where the film forming process and the modifying process were performed under the temperature condition illustrated in following Table 1 as an example (example) according to the embodiment of the present teachings was estimated. The film forming process and the modifying process in this evaluation are performed under the same condition as in this embodiment except for the presence or absence of the modifying process and the temperature condition. That is, the film forming process and the modifying process are performed in accordance with the above-described film forming processing step A and modifying processing step B by using the film forming processing apparatus 100 and the modifying processing apparatus 50, respectively.

TABLE 1

| | | PRESENCE OR | MODIFYING |
|---|---|---|---|
| | FILM FORMING | ABSENCE OF | PROCESSING |
| | PROCESSING | MODIFYING | TEMPERA- |
| CONDITION | TEMPERATURE | PROCESS | TURE |
| COMPARATIVE | 150° C. | NO | |
| EXAMPLE 1 | | | |
| COMPARATIVE | 200° C. | NO | |
| EXAMPLE 2 | | | |
| COMPARATIVE | 250° C. | NO | |
| EXAMPLE 3 | | | |
| EXAMPLE 1 | 250° C. | YES | 100° C. |
| EXAMPLE 2 | 250° C. | YES | 200° C. |

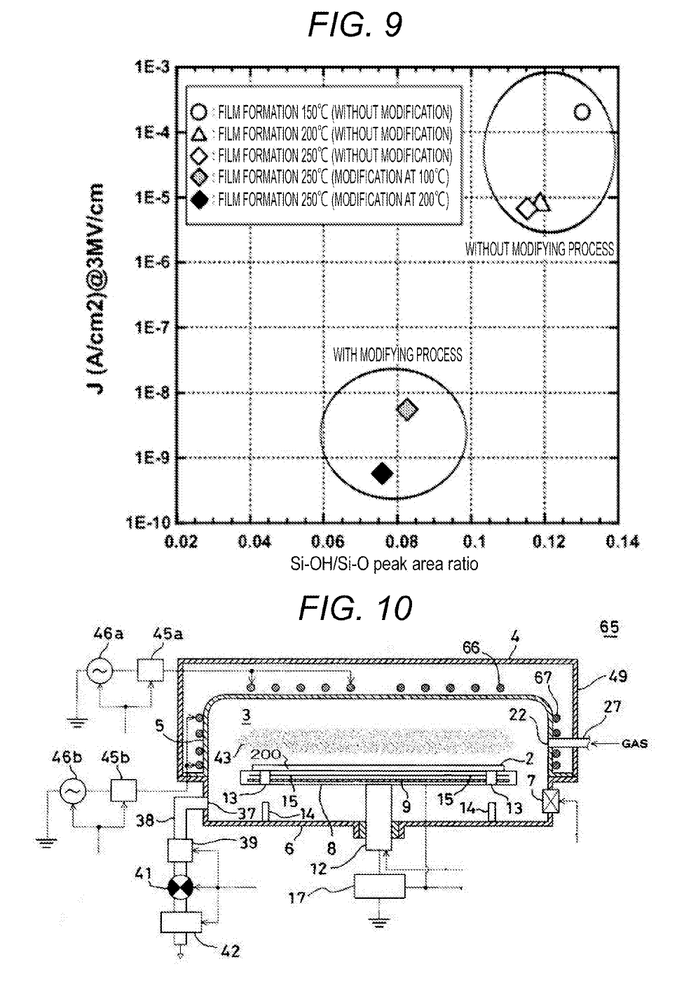

FIG. 9 is a view illustrating a characteristic of the silicon oxide film processed in Comparative Examples 1 to 3 and Examples 1 and 2 according to the embodiment of the present teachings. Values of an area ratio of a peak area of Si—OH to a peak area of Si—O obtained by performing Fourier transform-infrared spectroscopy (FT-IR) analysis on each silicon oxide film are plotted on the abscissa axis and indicate magnitude of a content ratio of the hydroxy group in the silicon oxide film. The larger the value of the Si—OH/Si—O peak area ratio, the larger the content ratio of the hydroxy group in the film, and the smaller the peak area value, the smaller the content ratio of the hydroxy group in the film. Values of a leakage current value of each silicon oxide film are plotted along the ordinate axis and specifically indicate magnitude of the leakage current per unit area (1 cm²) when voltage of 3 MV is applied to the film of unit length (1 cm). The larger the leakage current value, the worse the withstand voltage performance, and the smaller the leakage current value, the better the withstand voltage performance.

As illustrated in FIG. 9, in the case of Comparative Examples 1 to 3 (that is, when the silicon oxide film is formed at 300° C. or lower and then the modifying process is not performed by the hydrogen plasma), the hydroxy groups of an amount with which the Si—OH/Si—O peak area ratio by the FT-IR analysis exceeds 0.1 remain in each of the silicon oxide films. Such silicon oxide film might be practically problematic in terms of withstand voltage performance and chemical resistance performance.

In the case of Examples 1 and 2 according to the embodiment of the present teachings (that is, when the silicon oxide film is formed at 300° C. or lower and then the modifying process is performed by the hydrogen plasma), the Si—OH/Si—O peak area ratio by the FT-IR analysis is lower than 0.1 in each of the silicon oxide films, and it is understood that the contained amount of the hydroxy groups in the film is significantly reduced. That is, at the modifying processing step B according to this embodiment, by processing the silicon oxide film by using the hydrogen plasma, it is possible to reduce the contained amount of the hydroxy groups remaining in the film even by the process at a low temperature. In the case of Examples 1 and 2 according to the embodiment of the present teachings, the hydroxy groups in the film may be reduced until the Si—OH/Si—O peak area ratio becomes 0.1 or smaller, so that it is understood that the leakage current may be reduced to 1×10⁻⁸ A/cm² or lower without a practical problem.

[Effect of Using Hydrogen Plasma]

At the modifying processing step B of the first embodiment, the hydrogen gas (H₂ gas) is used as the processing gas when performing the plasma process, and the hydrogen radical generated by plasma excitation of the hydrogen gas is supplied to the silicon oxide film on the wafer 200, thereby modifying the silicon oxide film.

Unlike this embodiment, it is considered that the nitrogen gas (N₂ gas) or a nitrogen-containing gas, for example, is used as the processing gas for the plasma excitation, and a nitrogen radical generated by the plasma excitation is supplied to the silicon oxide film for modifying. Similarly, it is considered to perform the plasma excitation by using the oxygen gas (O₂ gas) or an oxygen-containing gas as the processing gas and supply an oxygen radical to the silicon oxide film for modifying. However, for the following reasons, it is more preferable to reduce the hydroxy group in the silicon oxide film and to repair the in-film defect, particularly by using the hydrogen radical.

Atomic radii of the hydrogen atom (H), nitrogen atom (N), and oxygen atom (O) are H: 0.37 Å, N: 0.65 Å, and 0: 0.6 Å, respectively. Alternatively, a crystal void of the silicon oxide film, for example, the SiO₂ film, is 0.6 Å to 0.8 Å. Herein, the hydrogen radical which is sufficiently smaller than the crystal void of the SiO₂ film may move freely in the SiO₂ film. Therefore, since the hydrogen radical reaches not only the surface of the SiO₂ film but also the inside of the film, this may react with the hydroxy groups in an entire film including the inside of the film to repair the in-film defects.

Both the nitrogen radical and oxygen radical having a small margin as compared with the crystal void of the SiO₂ film cannot enter the inside of the film to react with the hydroxy group inside the film, thereby repairing the in-film defect. That is, when modification is performed by using the nitrogen radical and oxygen radical, the repair of the in-film defect is limited to the vicinity of the film surface, so that a repairing effect (modifying effect) of the in-film defect is not sufficient. Therefore, it is preferable to use the hydrogen radical in the modifying process of reducing the hydroxy groups in the silicon oxide film and repairing the in-film defect. It is possible to perform the above-described modifying process while keeping the temperature of the wafer 200 low by performing the process by using the hydrogen radical generated by the plasma excitation, so that it is more preferable.

[Effect on Film with Low Void Ratio]

Herein, it is possible to perform the modifying process in this embodiment on the silicon oxide film having a high void ratio (for example, void ratio of 50% or higher) to reduce the hydroxy group and repair the defect. In this case, however, although a defect repairing effect may be expected to a certain degree, it is sometimes difficult to significantly reduce the void ratio only by repairing the defect and to improve denseness of the film.

Alternatively, when the modifying process is performed on the silicon oxide film having a low void ratio (for example, void ratio of 20% or lower) in the first embodiment, the in-film defect of the film with the low void ratio may be effectively repaired, so that the denseness of the film may be further improved and the performance of the film such as the withstand voltage performance and the chemical resistance performance may be further improved. Therefore, the modifying process of this embodiment is more preferable when an object is to repair the defect of the silicon oxide film having the low void ratio to improve the denseness of the film (for example, to improve the withstand voltage performance and chemical resistance performance of the film).

In the case of the modifying process by using the plasma on the silicon oxide film having the high void ratio, even when the nitrogen gas or oxygen gas is used as the processing gas, the nitrogen radical and oxygen radical may reach the inside of the film from the void in the film, so that the defect repairing effect is expected to a certain degree. However, in the case of modifying the silicon oxide film having the low void ratio, it is difficult for the nitrogen radical and oxygen radical to reach the inside of the film as described above, so that it is desirable to use the hydrogen radical as in this embodiment.

[Effect on Film without Alkyl Group Contained]

There is a case where an alkyl group (—R) in addition to the hydroxy group remains in the silicon oxide film to cause the in-film defect. The modifying processing step B by using the plasma in this embodiment is more preferable when reducing the hydroxy group and repairing the defect of the silicon oxide film in which a residual ratio of the alkyl group is small or the alkyl group is substantially not included for the following reason.

That is, when the modifying process is performed on the silicon oxide film containing the alkyl group in the film by using the hydrogen radical generated by the plasma excitation, the reaction of the hydrogen radical preferentially occurs with the alkyl group having lower bonding energy than the hydroxy group. Therefore, the defect repairing of the hydroxy group by the hydrogen radical is inhibited, and efficiency thereof is lowered. Furthermore, as compared with the hydroxy group formed of the oxygen atom and the hydrogen atom, the alkyl group formed of a carbon atom and a plurality of hydrogen atoms has a large volume, so that reduction in film density caused by loss of the alkyl group cannot be compensated only by repairing the defect of the hydroxy groups. Therefore, even if the silicon oxide film substantially containing the alkyl group is subjected to the modifying process by using the plasma in this embodiment, it is not possible to obtain an objective high-quality silicon oxide film with increased film density.

According to the first embodiment, one or more of the following effects may be obtained.

(a) By modifying the silicon oxide film containing the hydroxy group in the film with the hydrogen plasma, it is possible to reduce the hydroxy group in the film and repair the in-film defect caused by this. By repairing the defect in the film, the denseness of the film is increased, and in particular, the film quality (withstand voltage performance, chemical resistance performance and the like) as an insulator is improved.

(b) By modifying the silicon oxide film formed at a low process temperature of particularly 300° C. or lower by using the hydrogen plasma similarly at the process temperature of 300° C. or lower, it is possible to reduce the hydroxy groups remained in the film at a high percentage and repair the in-film defect caused by this. That is, since both the film forming process and the modifying process of the silicon oxide film may be performed under a low process temperature condition, it is possible to obtain the silicon oxide film having a performance as the insulator equivalent to that of a conventional silicon oxide film formed at a high process temperature (for example, 400° C. or higher) while minimizing the thermal damage on the device and pattern formed on the same substrate.

(c) By modifying the silicon oxide film containing the hydroxy group in the film, particularly by using the hydrogen plasma, it is possible to use the active species of hydrogen having a sufficiently small atomic radius with respect to the void of the silicon oxide film crystal, so that the hydroxy group remaining not only the vicinity of the film surface but also the inside the film may be sufficiently reduced, and the defect may be repaired.

(d) By modifying the silicon oxide film containing the hydroxy groups of an amount with which the Si—OH/Si—O peak area ratio by the FT-IR analysis exceeds 0.1 by using the hydrogen plasma, it is possible to significantly reduce the hydroxy groups in the film and repair the in-film defect caused by this, so that the improvement in the film quality is particularly remarkable.

(e) By oxidizing the polysilazane film with hydrogen peroxide, the silicon oxide film may be formed at a low temperature of 200° C. or lower. Therefore, by performing the modifying process by using the hydrogen plasma at a temperature of 200° C. or lower, it is possible to further reduce the thermal damage to the device and the pattern at the step of forming the silicon oxide film on the substrate.

### Another Example of First Embodiment

Although the case where the MMT apparatus is used as the modifying processing apparatus 50 is described in the first embodiment, other apparatus such as an inductively coupled plasma (ICP) apparatus or an electron cyclotron resonance (ECR) apparatus may also be used, for example, for performing the modifying processing step B.

FIG. 10 illustrates an ICP type plasma processing apparatus 65 which is another modifying processing apparatus used at the modifying processing step B according to the present teachings. In FIG. 10, the same reference signs are assigned to the equivalents of those in FIG. 6, and description thereof is omitted. The gas supply unit is not illustrated.

The ICP type plasma processing apparatus 65 is provided with dielectric coils 66 and 67 that generate the plasma by applying high-frequency power. The dielectric coil 66 is laid on an outside of a ceiling wall of the upper container 5 and the dielectric coil 67 is laid on an outside of an outer peripheral wall of the upper container 5. In the ICP type plasma processing apparatus 65 also, at least the H₂ gas is supplied from the gas supply pipe 27 into the processing chamber 3 through the gas introducing unit 22. In parallel with the supply of the processing gas, the high-frequency power is applied to the dielectric coils 66 and 67 being the plasma generating units, so that an electric field is generated by electromagnetic induction, and the supplied processing gas is excited by using the electric field as energy, it is possible to generate active species (such as hydrogen radicals).

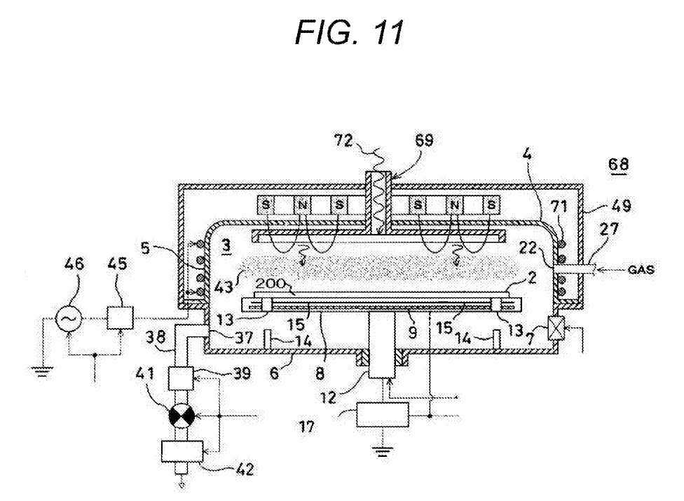

FIG. 11 illustrates an ECR type plasma processing apparatus 68 which is still another modifying processing apparatus used at the modifying processing step B according to the present teachings. In FIG. 11, the same reference signs are assigned to the equivalents of those in FIG. 6, and description thereof is omitted. The gas supply unit is not illustrated.

The ECR type plasma processing apparatus 68 is provided with a microwave introduction pipe 69 as a plasma generating unit for generating plasma by supplying microwaves and a dielectric coil 71. The microwave introduction pipe 69 is laid on an outside of a ceiling wall of the processing container 4 and the dielectric coil 71 is laid on an outside of the outer peripheral wall of the processing container 4. In the ECR type plasma processing apparatus 68 also, at least the H₂ gas is supplied from the gas supply pipe 27 to the processing chamber 3 through the gas introducing unit 22. In parallel with the supply of the processing gas, a microwave 72 is introduced into the microwave introduction pipe 69 which is the plasma generating unit, and then the microwave 72 is radiated into the processing chamber 3. By the microwave 72 and the high-frequency power from the dielectric coil 71, the supplied processing gas may be excited and the active species (hydrogen radical and the like) may be generated.

### Other Embodiments

Although the hydrogen gas (H₂ gas) is used as the processing gas at the modifying processing step B in the first embodiment, it is not limited thereto, and other hydrogen-containing gas may also be used as the processing gas.

Although the step of manufacturing the semiconductor device is described above, the present teachings are also applicable to any product requiring the silicon oxide film having high film density.

Although an example in which the silicon oxide film formed by supplying hydrogen peroxide to the PHPS film at the film forming processing step A is subjected to the plasma modifying process is described in the first embodiment, it is not limited thereto, and a similar plasma modifying process may be performed on the silicon oxide film formed by using a CVD method, an atomic layer deposition (ALD) method and the like. For example, the silicon oxide film may be formed of any one or a plurality of raw materials of hexamethyldisilazane (HMDS), hexamethylcyclotrisilazane (HMCTS), polycarbosilazane, polyorganosilazane, and trisilylamine (TSA).

Even with the silicon oxide film formed by using these methods, when the film is formed at a low process temperature (for example, room temperature to approximately 300° C.), the dehydration condensation reaction of the hydroxy group at the film forming step is inhibited, so that the hydroxy group in the film might remain beyond an allowable range of the film quality. Therefore, by performing the modifying process by using the hydrogen plasma according to the present teachings on the silicon oxide film formed at a low process temperature by using these methods, it is possible to reduce the hydroxy group in the film, and repair the in-film defect.

Furthermore, although an example in which the film forming processing step A and the modifying processing step B are performed by using the film forming processing apparatus 100 and the modifying processing apparatus 50, respectively, is described in the first embodiment, these processing steps may also be performed as a series of steps in a single substrate processing apparatus. As described above, the modifying process of the silicon oxide film at the modifying processing step B is not limited to that formed at the film forming processing step A.

Therefore, for example, the film forming processing step of forming the silicon oxide film on the substrate by the CVD method or the ALD method at a low process temperature may be performed by using the ICP type plasma processing apparatus 65, then the modifying process using the hydrogen plasma according to the present teachings may be subsequently performed on the silicon oxide film on the substrate without carrying out the substrate from the processing container.

With the technology according to the present teachings, even with a silicon oxide film formed at a low temperature, it is possible to obtain a film with an excellent characteristic with few in-film defects.

### REFERENCE SIGNS LIST

100 Film forming processing apparatus
121 Controller
200 Wafer (substrate)
203 Reaction tube
207 Heating unit
231 Gas exhaust pipe
233 Gas supply pipe
307 Hydrogen peroxide vapor generating device
50 Modifying processing apparatus
500 Controller
31 Processing gas supply source
34 Inert gas supply source
3 Processing chamber
8 Susceptor
9 Heater
231 Vacuum pump
233 Tubular electrode
65 ICP type plasma processing apparatus
68 ECR type plasma processing apparatus

1. A method of manufacturing a semiconductor device comprising:
(a) accommodating a substrate on a surface of which a silicon oxide film formed at a processing temperature of 300° C. or lower is formed in a processing container;
(b) plasma-exciting a hydrogen gas; and
(c) supplying hydrogen active species generated in (b) to the substrate.

2. The method of manufacturing a semiconductor device according to claim 1,
wherein, in (c), temperature of the substrate is set to be equal to or lower than temperature at which the silicon oxide film is formed.

3. The method of manufacturing a semiconductor device according to claim 1,
wherein, in (c), a pressure in the processing container is set to be equal to or higher than 50 Pa and equal to or lower than 200 Pa.

4. The method of manufacturing a semiconductor device according to claim 2,
wherein the silicon oxide film contains hydroxy groups of an amount with which a Si—OH/Si—O peak area ratio by FT-IR analysis exceeds 0.1.

5. The method of manufacturing a semiconductor device according to claim 4,
wherein the silicon oxide film has a void ratio of 20% or lower.

6. The method of manufacturing a semiconductor device according to claim 4,
wherein the silicon oxide film does not substantially contain an alkyl group.

7. The method of manufacturing a semiconductor device according to claim 1,
wherein the silicon oxide film is formed by oxidizing a silicon-containing film formed on the substrate with hydrogen peroxide at 200° C. or lower.

8. The method of manufacturing a semiconductor device according to claim 7,
wherein the silicon-containing film is a polysilazane film.

9. The method of manufacturing a semiconductor device according to claim 7,
wherein, in (c), the temperature of the substrate is set to 200° C. or lower.

10. A method of manufacturing a semiconductor device comprising:
(a) forming a silicon oxide film on a substrate surface at a processing temperature of 300° C. or lower;
(b) plasma-exciting a hydrogen gas; and
(c) supplying hydrogen active species generated in (b) to the substrate.

11. The method of manufacturing a semiconductor device according to claim 10,
wherein (a) and (c) are performed in the same processing container.

12. A non-transitory computer-readable recording medium recording a program which allows a computer to execute:
(a) accommodating a substrate on a surface of which a film including a silazane bond is formed in a first processing container;
(b) supplying a hydrogen peroxide gas into the first processing container and modifying the film including the silazane bond to a silicon oxide film at a processing temperature of 200° C. or lower;
(c) carrying out the substrate on the surface of which the silicon oxide film is formed from the first processing container;
(d) accommodating the substrate on the surface of which the silicon oxide film is formed in a second processing container;
(e) plasma-exciting a hydrogen gas; and
(f) supplying hydrogen active species generated in (e) to the substrate on the surface of which the silicon oxide film is formed.
